(19) United States
(12) Patent Application Publication
(10) Pub. No.: US 2010/0047653 A1
(43) Pub. Date: Feb. 25, 2010

(54) PRINTED CIRCUIT BOARD AND FUEL CELL

(75) Inventors: Hiroshi YAMAZAKI, Osaka (JP); Noriaki AIMOTO, Osaka (JP); Taiki SUEYOSHI, Osaka (JP); Hiroyuki HANAZONO, Osaka (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: NITTO DENKO CORPORATION, Osaka (JP)

(21) Appl. No.: 12/544,254

(22) Filed: Aug. 20, 2009

(30) Foreign Application Priority Data
Aug. 25, 2008 (JP) 2008-215210

(51) Int. Cl. H01M 8/10; H05K 1/00

(52) U.S. Cl. 429/30; 174/250

(57) ABSTRACT

A pair of rectangular collector portions and extraction conductor portions that each extend in a long-sized shape from the respective collector portions are formed on one surface of a base insulating layer. A carbon containing layer is formed on the base insulating layer to cover the collector portion and the extraction conductor portion excluding a tip. A carbon containing layer and a solder resist layer are formed on the base insulating layer to cover the collector portion and the extraction conductor portion excluding a tip. The solder resist layer is formed to cover a portion of the extraction conductor portion above a bend portion.

### BACKGROUND OF THE INVENTION

1. Field of the Invention

The present invention relates to a printed circuit board and a fuel cell using the same.

2. Description of the Background Art

Batteries that are small in size and have high capacity are desired for mobile equipment such as cellular telephones. Therefore, fuel cells capable of providing higher energy density than conventional batteries such as lithium secondary batteries have been developed. Examples of the fuel cells include a direct methanol fuel cell.

In the direct methanol fuel cell, methanol is decomposed by a catalyst, forming hydrogen ions. The hydrogen ions are reacted with oxygen in the air to generate electrical power. In this case, chemical energy can be converted into electrical energy with extremely high efficiency, so that significantly high energy density can be obtained.

A flexible printed circuit board (hereinafter abbreviated as an FPC board), for example, is provided as a collector circuit within such a direct methanol fuel cell (see JP 2004-200064 A, for example). Here, the configuration of the conventional fuel cell is described referring to FIG. 6. FIG. 6 (a) is a plan view of the FPC board used in the conventional fuel cell, and FIG. 6 (b) is a sectional view showing the configuration of the conventional fuel cell.

As shown in FIG. 6 (a), a pair of conductor layers 52a, 52b is formed on one surface of the FPC board 51. In addition, extraction electrodes 53a, 53b are provided so as to extend out of the conductor layers 52a, 52b, respectively.

As shown in FIG. 6 (b), a fuel cell 50 is constituted by the FPC board 51, a film electrode junction 54 and a housing 55. The film electrode junction 54 is composed of a polyelectrolyte film 54a, a fuel electrode 54b and an air electrode 54c. The fuel electrode 54b is formed on one surface of the polyelectrolyte film 54a, and the air electrode 54c is formed on the other surface of the polyelectrolyte film 54a. The housing 55 is composed of a pair of half portions 55a, 55b. The half portion 55a is provided with fuel passages 56 into which fuel (methanol) flows, and the half portion 55b is provided with air passages 57 into which air flows.

The FPC board 51 is bent with its one surface on which the conductor layers 52a, 52b are formed as an inner side. The film electrode junction 54 is sandwiched between the conductor layers 52a, 52b of the bent FPC board 51. Gaskets 58a, 58b are disposed in the periphery of the FPC board 51. In this state, the bent FPC board 51 excluding the extraction electrodes 53a, 53b is housed in the housing 55 composed of the half portions 55a, 55b. Various types of external circuits such as electronic components are electrically connected to the extraction electrodes 53a, 53b that project from the housing 55.

In this fuel cell 50, methanol is supplied to the fuel electrode 54b of the film electrode junction 54 through the fuel passages 56 of the half portion 55a. Moreover, air is supplied to the air electrode 54c of the film electrode junction 54 through the air passages 57 of the half portion 55b. In this case, methanol is decomposed into hydrogen ions and carbon dioxide by a catalyst to form electrons in the fuel electrode 54b.

The hydrogen ions decomposed from methanol pass through the polyelectrolyte film 54a to reach the air electrode 54c, and then react on the catalyst with oxygen in the air supplied to the air electrode 54c. Thus, the electrons are consumed while water is formed in the air electrode 54c. This causes the electrons to move between the conductor layers 52a, 52b of the FPC board 51 and supplies electrical power to the external circuits.

Generally, copper is used as the conductor layers 52a, 52b of the FPC board 51. Therefore, the conductor layers 52a, 52b may be affected by acid of methanol or the like supplied to the fuel cell 50, thus corroding in some cases.

### SUMMARY OF THE INVENTION

An object of the present invention is to provide a printed circuit board that is prevented from corroding due to acid and a fuel cell including the same.

(1) According to an aspect of the present invention, a printed circuit board used in a fuel cell includes an insulating layer that has one surface and the other surface while having, on the one surface, first and second regions that are adjacent to each other and a third region that is adjacent to the first region, a first conductor portion formed on the first region of the insulating layer, a second conductor portion formed on the second region of the insulating layer, a first extraction portion that is integrally formed with the first conductor portion and extends from the first region to the third region of the insulating layer, a second extraction portion that is integrally formed with the second conductor portion and extends from the second region to the third region through the first region of the insulating layer, a first coating layer formed to cover the first conductor portion and the first extraction portion on at least the first region of the insulating layer, and a second coating layer formed to cover the second conductor portion and the second extraction portion on at least the first and second regions of the insulating layer, wherein the insulating layer can be bent at a bend portion between the first region and the second region such that the first region and the second region are opposite to each other, the second coating layer includes a first coating portion that covers a portion, above the bend portion of the insulating layer, of the second extraction portion, and a second coating portion formed on a region of the insulating layer excluding the bend portion, the first coating layer and the second coating portion of the second coating layer are each made of a resin composition containing carbon, and the first coating portion of the second coating layer has higher flexibility than the second coating portion of the second coating layer.

In the printed circuit board, the first conductor portion and the first extraction portion are coated with the first coating layer, and the second conductor portion and the second extraction portion are coated with the second coating layer. Therefore, in the fuel cell using the printed circuit board, corrosion of the first and second conductor portions and the first and second extraction portions can be prevented even in a state where acid of methanol or the like supplied as fuel is in contact with the printed circuit board.

Moreover, the first coating layer and the second coating portion of the second coating layer contain carbon, thereby having electrical conductivity. Therefore, collecting actions in the first and second conductor portions are not inhibited in the fuel cell.

Moreover, the insulating layer is bent along the bend portion such that the first region and the second region are opposite to each other in the fuel cell. In this case, the portion, above the bend portion, of the second extraction portion is coated with the first coating portion having high flexibility. Therefore, a crack or the like is not formed in the first coating portion even though the insulating layer is bent along the bend portion. Accordingly, the portion, above the bend portion, of the second extraction portion is reliably prevented from corroding.

In addition, the third region of the insulating layer is extracted to the outside of the fuel cell. At least part of the first extraction portion and at least part of the second extraction portion on the third region are exposed to the outside of the fuel cell.

In this case, since the at least part of the first extraction portion and the at least part of the second extraction portion are in close proximity to each other on the same plane to be exposed, the first and second extraction portions can be easily and accurately aligned with and connected to terminals of external circuits. This improves reliability of connection between the printed circuit board and the external circuits.

(2) The first coating portion of the second coating layer may be made of a resin material. In this case, flexibility of the first coating portion is sufficiently ensured while the second extraction portion above the bend portion can be reliably protected.

(3) A thickness of the first coating portion of the second coating layer may be not less than 5 μm and not more than 20 μm, and a thickness of each of the first coating layer and the second coating portion of the second coating layer may be not less than 5 μm and not more than 30 μm.

In this case, the flexibility of the first coating portion is more sufficiently ensured while the second extraction portion above the bend portion can be reliably protected.

In addition, the first coating layer and the second coating portion of the second coating layer suppress an increase in a thickness of the printed circuit board and reliably prevents corrosion of the first and second conductor portions and the first and second extraction portions in the region of the insulating layer excluding the bend portion.

(4) The first coating portion of the second coating layer may be made of a resin composition containing carbon, and a thickness of the first coating portion of the second coating layer may be smaller than a thickness of the second coating portion of the second coating layer.

In this case, the flexibility of the first coating portion is sufficiently ensured while the second extraction portion above the bend portion can be reliably protected.

(5) The thickness of the first coating portion of the second coating layer may be not less than 5 μm and not more than 20 μm, and each of a thickness of the first coating layer and the thickness of the second coating portion of the second coating layer may be not less than 5 μm and not more than 30 μm.

In this case, the flexibility of the first coating portion is more sufficiently ensured while the second extraction portion above the bend portion can be more reliably protected.

In addition, the first coating layer and the second coating portion of the second coating layer suppress the increase in the thickness of the printed circuit board and reliably prevents corrosion of the first and second conductor portions and the first and second extraction portions in the region of the insulating layer excluding the bend portion.

(6) According to another aspect of the present invention, a fuel cell includes the printed circuit board according to the first invention, a cell element, and a housing that houses the printed circuit board and the cell element, wherein the cell element is arranged between the first and second regions in a state where the first and second regions of the insulating layer of the printed circuit board are bent along the bend portion with the one surface as an inner side, and the third region of the insulating layer is outwardly extracted from the housing such that at least part of the first extraction portion and at least part of the second extraction portion are exposed to an outside of the housing.

The insulating layer of the printed circuit board is bent along the bend portion arranged between the first region and the second region such that the first region and the second region are opposite to each other in the fuel cell. The cell element including a fuel electrode and an air electrode is arranged between the first and second conductor portions on the bent insulating layer. The third region of the insulating layer of the printed circuit board is extracted from the housing to the outside such that the at least part of the first extraction portion and the at least part of the second extraction portion are exposed to the outside of the housing.

The first conductor portion and the first extraction portion of the printed circuit board are coated with the first coating layer, and the second conductor portion and the second extraction portion are coated with the second coating layer. Therefore, corrosion of the first and second conductor portions and the first and second extraction portions can be prevented even in a state where acid of methanol or the like supplied as fuel is in contact with the printed circuit board.

Moreover, the first coating layer and the second coating portion of the second coating layer contain carbon, thereby having electrical conductivity. Therefore, collecting actions in the first and second conductor portions are not inhibited in the housing.

Furthermore, the portion of the second extraction portion above the bend portion of the insulating layer is coated with the first coating portion having high flexibility. Therefore, a crack or the like is not formed in the first coating portion even though the insulating layer is bent along the bend portion. Accordingly, the portion of the second extraction portion above the bend portion is reliably prevented from corroding.

In addition, the at least part of the first extraction portion and the at least part of the second extraction portion of the printed circuit board are exposed on the same plane in the outside of the housing. Thus, the first and second extraction portions can be easily and accurately aligned with and connected to terminals of external circuits. This improves the reliability of connection between the printed circuit board and the external circuits.

According to the present invention, corrosion of the first and second conductor portions and the first and second extraction portions can be prevented even in the state where acid of methanol or the like is in contact with the printed circuit board. In addition, a crack or the like is not formed in the first coating portion even though the insulating layer is bent. Accordingly, the portion of the second extraction portion above the bend portion can be reliably prevented from corroding.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a diagram showing the configuration of a flexible printed circuit board according to the present embodiment;

FIG. 2 is a sectional view for use in explaining steps in a manufacturing method of the flexible printed circuit board;

FIG. 3 is a sectional view for use in explaining steps in the manufacturing method of the flexible printed circuit board;

FIG. 4 is a diagram showing the configuration of a fuel cell using the flexible printed circuit board of FIG. 1;

FIG. 5 is a diagram showing the configuration of a flexible printed circuit board according to another embodiment; and

FIG. 6 is a diagram showing a fuel cell using a conventional printed circuit board.

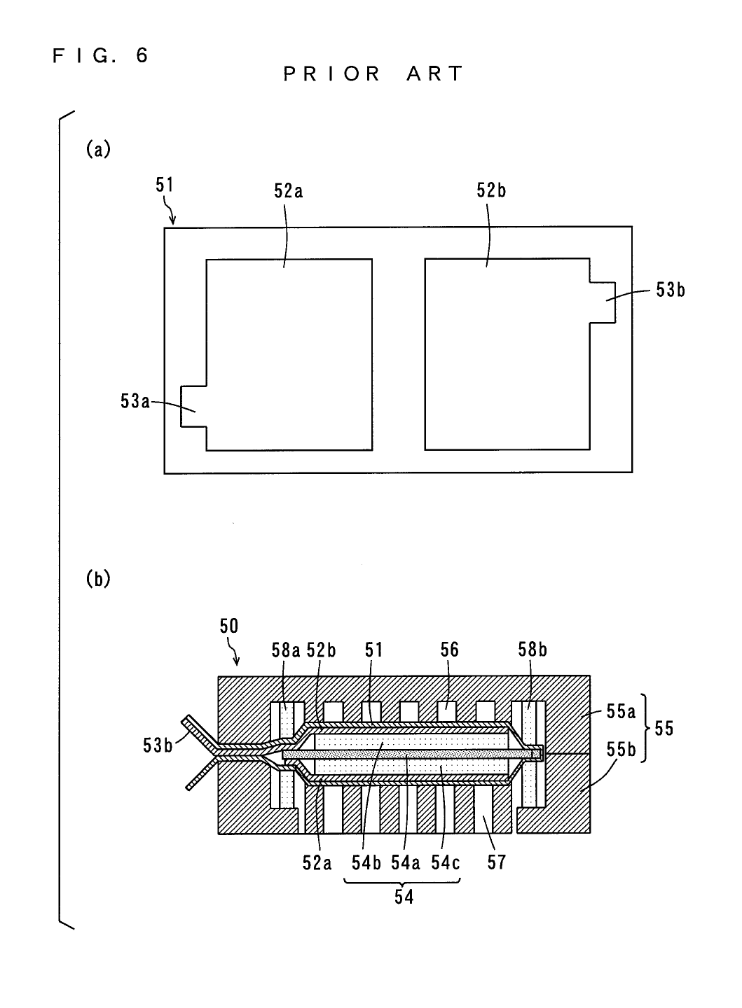

### DESCRIPTION OF THE PREFERRED EMBODIMENTS

A printed circuit board and a fuel cell according to an embodiment of the present invention will now be described while referring to the drawings. Note that a flexible printed circuit board having a flexuous property is described as an example of the printed circuit board in the present embodiment.

### (1) Configuration of the Flexible Printed Circuit Board

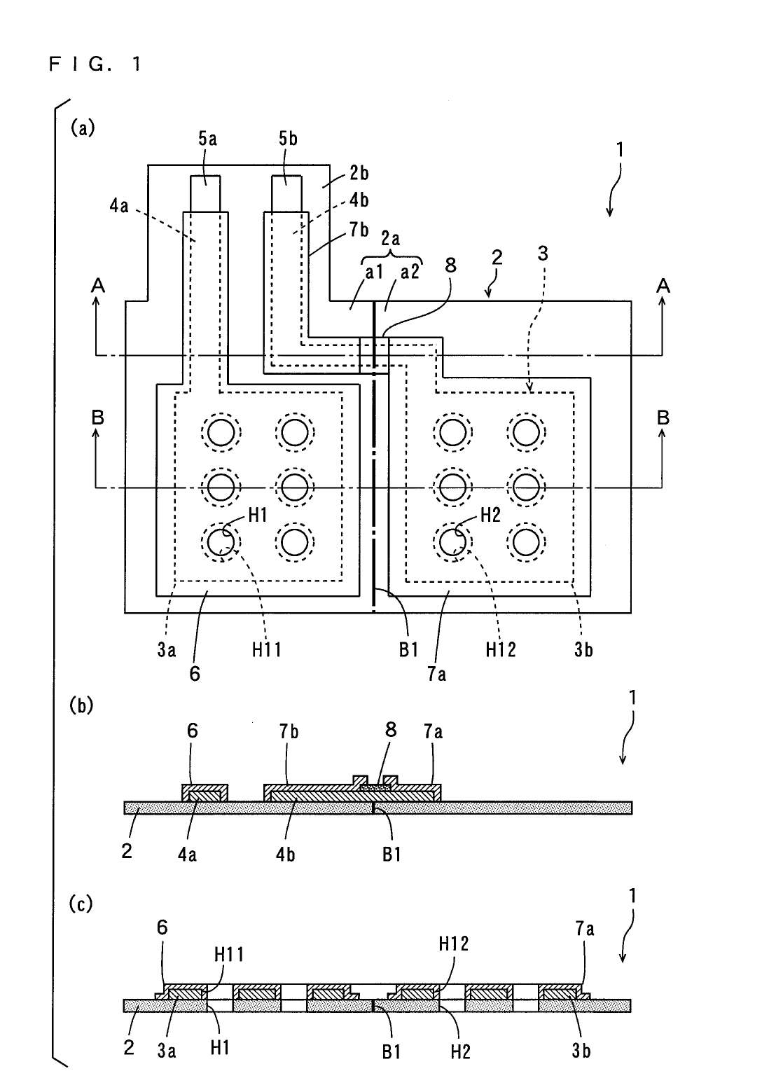

FIG. 1 (a) is a plan view of the flexible printed circuit board according to the present embodiment, FIG. 1 (b) is a sectional view taken along the line A-A of the flexible printed circuit board of FIG. 1 (a), and FIG. 1 (c) is a sectional view taken along the line B-B of the flexible printed circuit board of FIG. 1 (a). In the following description, the flexible printed circuit board is abbreviated as the FPC board.

As shown in FIG. 1 (a) to (c), the FPC board 1 includes a base insulating layer 2 made of polyimide, for example. The base insulating layer 2 is composed of a rectangular first insulating portion 2a and a second insulating portion 2b that outwardly extends from one side of the first insulating portion 2a. Hereinafter, the above-mentioned one side of the first insulating portion 2a and the other one side parallel thereto are referred to as lateral sides, and the other pair of sides vertical to the lateral sides of the first insulating portion 2a are referred to as end sides.

A bend portion B1 is provided in the first insulating portion 2a of the base insulating layer 2 so as to be parallel to the end sides and to divide the first insulating portion 2a into two substantially equal parts. As will be described later, the first insulating portion 2a is bent along the bend portion B1. The bend portion B1 may be a shallow groove with a line shape, a mark with a line shape or the like, for example. Alternatively, there may be nothing at the bend portion B1 if the first insulating portion 2a can be bent at the bend portion B1.

The first insulating portion 2a is divided into one region and the other region with the bend portion B1 as a boundary. Hereinafter, the one region is referred to as a first regional and the other region is referred to as a second region a2. The second insulating portion 2b is formed so as to outwardly extend from a lateral side of the first regional of the first insulating portion 2a.

A plurality of (six in this example) openings H1 are formed in the first regional of the first insulating portion 2a. A plurality of (six in this example) openings H2 are formed in the second region a2 of the first insulating portion 2a.

The conductor layer 3 made of copper, for example, is formed on one surface of the base insulating layer 2. The conductor layer 3 is composed of a pair of rectangular collector portions 3a, 3b and extraction conductor portions 4a, 4b extending in long-sized shapes from the collector portions 3a, 3b, respectively.

Each of the collector portions 3a, 3b has a pair of lateral sides parallel to the lateral sides of the first insulating portion 2a and a pair of end sides parallel to the end sides of the first insulating portion 2a. The collector portion 3a is formed in the first regional of the first insulating portion 2a, and the collector portion 3b is formed in the second region a2 of the first insulating portion 2a.

Openings H11 each having a larger diameter than that of the opening H1 are formed in portions, above the openings H1 of the base insulating layer 2, of the collector portion 3a. Openings H12 each having a larger diameter than that of the opening H2 are formed in portions, above the openings H2 of the base insulating layer 2, of the collector portion 3b.

The extraction conductor portion 4a is formed so as to linearly extend from the lateral side of the collector portion 3a to a region on the second insulating portion 2b. The extraction conductor portion 4b is formed so as to extend from the lateral side of the collector portion 3b and bend to a region on the second insulating portion 2b.

A carbon containing layer 6 is formed on the base insulating layer 2 to cover the extraction conductor portion 4a excluding a tip and the collector portion 3a. The carbon containing layer 6 is made of a resin composition produced by containing carbon (carbon black, for example) in a resin material such as polyimide. The carbon containing layer 6 comes in contact with an upper surface of the base insulating layer 2 in the openings H11 of the collector portion 3a.

Carbon containing layers 7a, 7b and a solder resist layer 8 are formed on the base insulating layer 2 to cover the extraction conductor portion 4b excluding a tip and the collector portion 3b. The solder resist layer 8 is formed to cover a portion of the extraction conductor portion 4b above the bend portion B1. The carbon containing layer 7a is formed on one side of the solder resist layer 8 to cover the extraction conductor portion 4b and the collector portion 3b. The carbon containing layer 7b is formed on the other side of the solder resist layer 8 to cover the extraction conductor portion 4b excluding the tip.

The solder resist layer 8 is made of polyimide, for example. Similarly to the carbon containing layer 6, the carbon containing layers 7a, 7b are each made of a resin composition produced by containing carbon (carbon black, for example) in a resin material such as polyimide. The carbon containing layer 7a comes in contact with the upper surface of the base insulating layer 2 in the openings H12 of the collector portion 3b.

Note that the solder resist layer 8 and each of the carbon containing layers 7a, 7b are preferably formed to overlap with each other such that the extraction conductor portion 4b is not exposed at boundary portions between the solder resist layer 8 and each of the carbon containing layers 7a, 7b. While end portions of the carbon containing layers 7a, 7b are formed on the solder resist layer 8 in FIG. 1 (b), end portions of the solder resist layer 8 may be formed on the carbon containing layers 7a, 7b.

In the following description, the exposed tips of the extraction conductor portions 4a, 4b are referred to as extraction electrodes 5a, 5b.

### (2) Manufacturing Method of the FPC Board

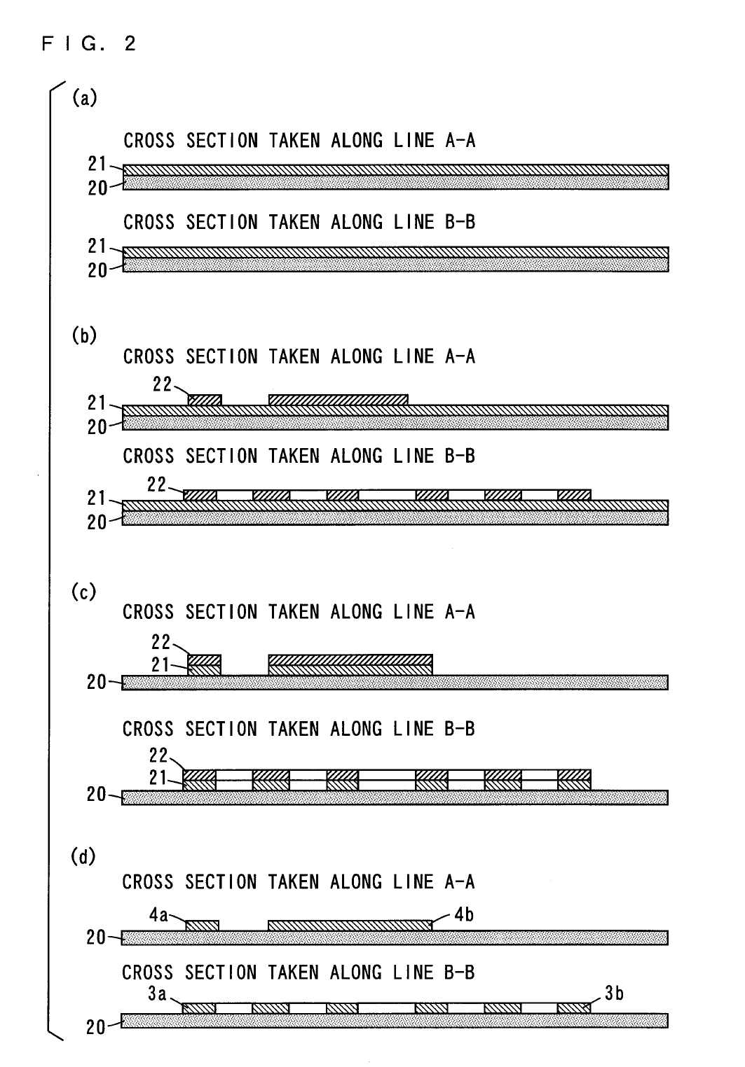

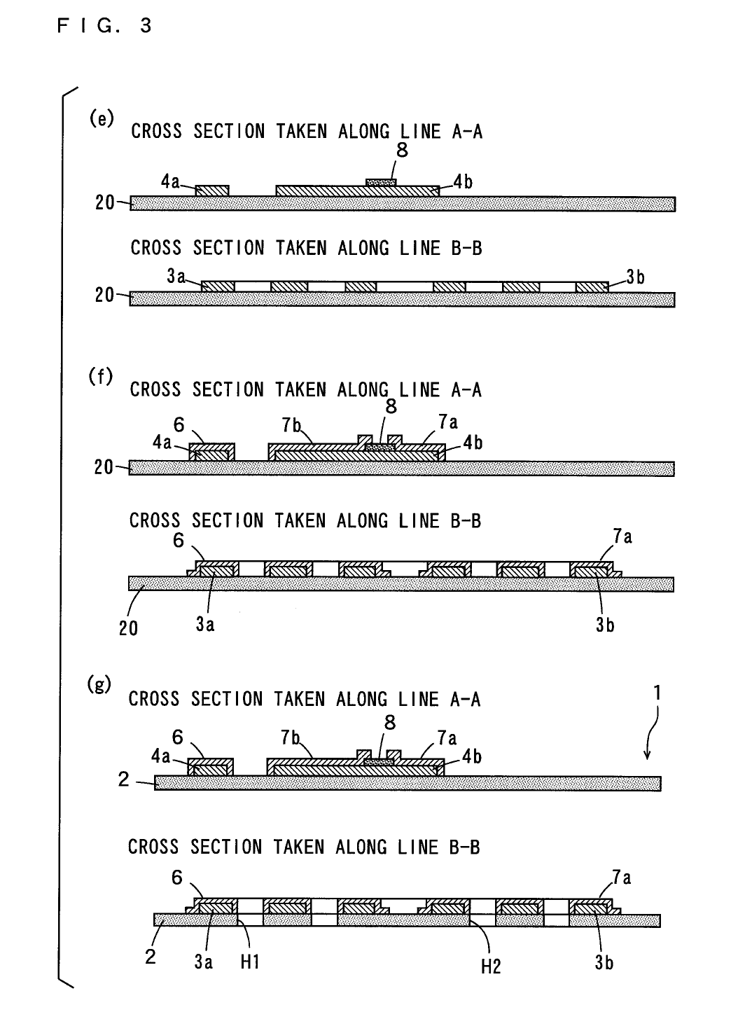

Next, description is made of a manufacturing method of the FPC board 1 shown in FIG. 1. FIG. 2 and FIG. 3 are sectional views for use in explaining steps in the manufacturing method of the FPC board 1. FIGS. 2 and 3 show the manufacturing steps in the cross section taken along the line A-A and the cross section taken along the line B-B of FIG. 1.

First, a two-layer base material having an insulating film 20 made of polyimide, for example, and a conductor film 21 made of copper, for example, is prepared as shown in FIG. 2 (a). The thickness of the insulating film 20 is 25 μm, for example, and the thickness of the conductor film 21 is 18 μm, for example.

Next, an etching resist 22 having a predetermined pattern is formed on the conductor film 21 as shown in FIG. 2 (b). The etching resist 22 is formed by forming a resist film on the conductor film 21 using a dry film resist or the like, exposing the resist film in a predetermined pattern, and then developing the resist film, for example.

Then, the conductor film 21 excluding a region below the etching resist 22 is removed by etching as shown in FIG. 2 (c). The etching resist 22 is subsequently removed by a stripping liquid as shown in FIG. 2 (d). In this manner, the conductor layer 3 composed of the collector portions 3a, 3b and the extraction conductor portions 4a, 4b is formed on the insulating film 20.

Next, the solder resist layer 8 is formed in a predetermined region on the insulating film 20 to cover part of the conductor layer 3 (part of the extraction conductor portion 4b) as shown in FIG. 3 (e). Specifically, the solder resist layer 8 is formed by applying or laminating polyimide on the insulating film 20, and subsequently exposing the polyimide in a predetermined shape, followed by development, for example. The thickness of the solder resist layer 8 is 12 μm, for example.

Then, the carbon containing layers 7a, 7b are formed on the both sides of the solder resist layer 8 to cover the extraction conductor portion 4b excluding the tip and the collector portion 3b, as shown in FIG. 3 (f). The carbon containing layer 6 is formed to cover the extraction conductor portion 4a excluding the tip and the collector portion 3a.

Specifically, the carbon containing layers 6, 7a, 7b are formed by applying the resin composition containing carbon black on resin such as polyimide, followed by curing. Here, carbon contained in the carbon containing layers 6, 7a, 7b is not carbon constituting resin as an organic compound, but carbon having electrical conductivity. The foregoing carbon is elemental carbon such as carbon black, for example.

Note that in this case, the end portions of the carbon containing layers 7a, 7b are preferably formed on the solder resist layer 8. The thickness of each of the carbon containing layers 6, 7a, 7b is 20 μm, for example.

Then, the insulating film 20 is cut in a predetermined shape and the openings H1, H2 are formed in the insulating layer 20 as shown in FIG. 3 (g). In this manner, the FPC board 1 composed of the base insulating layer 2, the conductor layer 3, the carbon containing layers 6, 7a, 7b and the solder resist layer 8 is completed.

Note that the thickness of the base insulating layer 2 is preferably not less than 5 μm and not more than 50 μm, and more preferably not less than 12.5 μm and not more than 25 μm. The thickness of the conductor layer 3 is preferably not less than 3 μm and not more than 35 μm, and more preferably not less than 5 μm and not more than 20 μm. The thickness of each of the carbon containing layers 6, 7a, 7b is preferably not less than 5 μm and not more than 30 μm, and more preferably not less than 5 μm and not more than 20 μm. The thickness of the solder resist layer 8 is preferably not less than 5 μm and not more than 20 μm, and more preferably not less than 5 μm and not more than 15 μm.

Each of the carbon containing layers 6, 7a, 7b preferably has a carbon content of not less than 10% by weight and not more than about 70% by weight, and more preferably not less than 20% by weight and not more than 50% by weight.

While the conductor layer 3 is formed by a subtractive method in FIGS. 2 and 3, the conductor layer 3 may be formed by another manufacturing method such as a semi-additive method.

In addition, while the solder resist layer 8 is formed by an exposure method in FIGS. 2 and 3, the solder resist layer 8 with a predetermined shape may be formed by a printing technique. In the case, a thermal curing treatment may be performed to the solder resist layer 8.

While the carbon containing layers 6, 7a, 7b are formed after formation of the solder resist layer 8 in FIGS. 2 and 3, the solder resist layer 8 may be formed after formation of the carbon containing layers 6, 7a, 7b. In this case, the end portions of the solder resist layer 8 is preferably formed on the carbon containing layers 7a, 7b.

### (3) Fuel Cell Employing the FPC Board

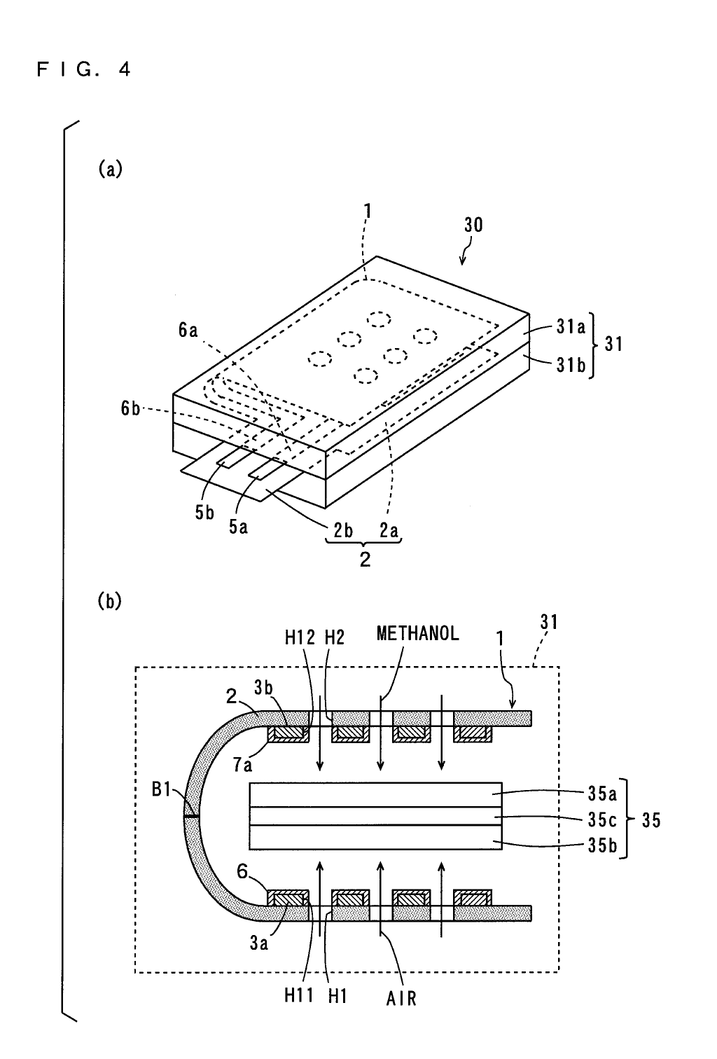

Next, description is made of a fuel cell employing the above-described FPC board 1. FIG. 4 (a) is a perspective view showing the appearance of the fuel cell employing the above-described FPC board 1, and FIG. 4 (b) is a diagram for use in explaining actions in the fuel cell.

As shown in FIG. 4 (a), the fuel cell 30 includes a rectangular parallelepiped housing 31 composed of half portions 31a, 31b. The FPC board 1 is sandwiched between the half portions 31a, 31b while being bent along the bend portion B1 of FIG. 1 with the one surface on which the conductor layer 3 (FIG. 1), the carbon containing layers 6, 7a, 7b and the solder resist layer 8 are formed as its inner side.

The second insulating portion 2b of the base insulating layer 2 of the FPC board 1 is outwardly extracted from a clearance between the half portions 31a, 31b. This causes the extraction electrodes 5a, 5b on the second insulating portion 2b to be exposed to the outside of the housing 31. Terminals of various types of external circuits are electrically connected to the extraction electrodes 5a, 5b.

As shown in FIG. 4 (b), an electrode film 35 is arranged between the collector portion 3a and the collector portion 3b of the bent FPC board 1 in the housing 31. The electrode film 35 is composed of a fuel electrode 35a, an air electrode 35b and an electrolyte film 35c. The fuel electrode 35a is formed on one surface of the electrolyte film 35c, and the air electrode 35b is formed on the other surface of the electrolyte film 35c. The fuel electrode 35a of the electrode film 35 is opposite to the collector portion 3b of the FPC board 1, and the air electrode 35b is opposite to the collector portion 3a of the FPC board 1.

Fuel is supplied to the fuel electrode 35a of the electrode film 35 through the openings H2, H12 of the FPC board 1. Note that methanol is used as the fuel in the present embodiment. Air is supplied to the air electrode 35b of the electrode film 35 through the openings H1, F11 of the FPC board 1.

In this case, methanol is decomposed into hydrogen ions and carbon dioxide in the fuel electrode 35a, forming electrons.

The formed electrons are led from the collector portion 3b to the extraction electrode 5b (FIG. 4 (a)) of the FPC board 1. Hydrogen ions decomposed from methanol pass through the electrolyte film 35c to reach the air electrode 35b. In the air electrode 35b, hydrogen ions and oxygen are reacted while the electrons led from the extraction electrode 5a (FIG. 4 (a)) to the collector portion 3a are consumed, thereby forming water. In this manner, electrical power is supplied to the external circuits connected to the extraction electrodes 5a, 5b.

### (4) Effects of the Present Embodiment

In the FPC board 1 of the present embodiment, the surface of the conductor layer 3 is covered with the carbon containing layers 6, 7a, 7b and the solder resist layer 8. Therefore, corrosion of the conductor layer 3 can be prevented even in a state where acid produced by reaction of methanol or the like is in contact with the surface of the FPC board 1 in the fuel cell 30. In addition, the carbon containing layers 6, 7a, 7b contain carbon, thereby ensuring electrical conductivity between the electrode film 35 and the collector portions 3a, 3b of the conductor layer 3. Moreover, since an expensive material such as Au (gold) need not be used, corrosion of the conductor layer 3 can be prevented at low cost. Furthermore, ion migration of the conductor layer 3 can be prevented by the carbon containing layers 6, 7a, 7b.

The solder resist layer 8 made of the resin material is formed in the region above the bend portion B1 of the base insulating layer 2. The solder resist layer 8 has higher flexibility than the carbon containing layers 6, 7a, 7b. Thus, a crack or the like is not formed in the solder resist layer 8 even though the FPC board 1 is bent along the bend portion B1. Accordingly, above the bend portion B1, the extraction conductor portion 4b is reliably prevented from coming in contact with acid, and corrosion of the conductor layer 3 is reliably prevented.

In the FPC board 1 of the present embodiment, the extraction electrodes 5a, 5b are arranged side by side on the same plane of the common second insulating portion 2b of the base insulating layer 2. Accordingly, in the fuel cell 30 employing the FPC board 1, the extraction electrodes 5a, 5b can be easily and accurately aligned with and connected to terminals of external circuits. This improves reliability of connection between the external circuits and the fuel cell 30.

### (5) Another Embodiment

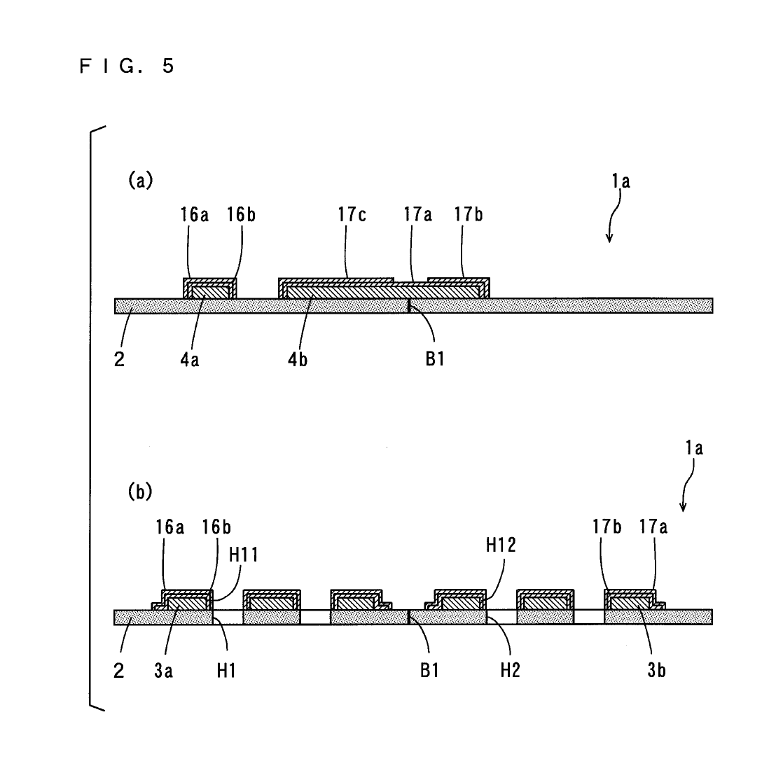

An FPC board according to another embodiment of the present invention is described by referring to differences from the FPC board 1 shown in FIG. 1. FIG. 5 is a sectional view of the FPC board according to the another embodiment. Note that a cross section shown in FIG. 5 (a) corresponds to the cross section taken along the line A-A in FIG. 1, and a cross section shown in FIG. 5 (b) corresponds to the cross section taken along the line B-B in FIG. 1.

In the FPC board 1a shown in FIG. 5, carbon containing layers 16a, 16b, 17a, 17b, 17c are formed instead of the carbon containing layers 6, 7a, 7b and the solder resist layer 8.

The carbon containing layers 16a, 16b are formed to overlap on the base insulating layer 2 to cover the extraction conductor portion 4a excluding the tip and the collector portion 3a.

The carbon containing layers 17a is formed on the base insulating layer 2 to cover the extraction conductor portion 4b excluding the tip and the collector portion 3b. The carbon containing layers 17b, 17c are formed to overlap with the carbon containing layer 17a on both sides of the portion of the extraction conductor portion 4b above the bend portion 4B, respectively. In this case, only the carbon containing layer 17a is formed and the carbon containing layers 17b, 17c are not formed in the portion of the extraction conductor portion 4b above the bend portion B1.

Similarly to the carbon containing layers 6, 7a, 7b, each of the carbon containing layers 16a, 16b, 17a, 17b, 17c is made of a resin composition produced by containing carbon (carbon black, for example) in a resin material such as polyimide. The carbon containing layers 16a, 16b are in contact with the upper surface of the base insulating layer 2 in the openings H11 of the collector portion 3a. The carbon containing layers 17a, 17b are in contact with the upper surface of the base insulating layer 2 in the openings H12 of the collector portion 3b.

The thickness of each of the carbon containing layer 16a, 17a is preferably not less than 5 μm and not more than 20 μm, and more preferably not less than 5 μm and not more than 12 μm. The thickness of each of the carbon containing layers 16b, 17b, 17c is preferably not less than 5 μm and not more than 20 μm, and more preferably not less than 5 μm and not more than 12 μm.

The surface of the conductor layer 3 is covered with the carbon containing layers 16a, 16b, 17a, 17b, 17c in the FPC board 1a of the present embodiment. Therefore, in the fuel cell 30 using the FPC board 1a, corrosion of the conductor layer 3 can be prevented even in a state where acid of methanol or the like is in contact with the surface of the FPC board 1a. In addition, the carbon containing layers 16a, 16b, 17a, 17b, 17c contain carbon, thereby ensuring electrical conductivity between the electrode film 35 and the collector portions 3a, 3b of the conductor layer 3. Moreover, since an expensive material such as Au (gold) need not be used, corrosion of the conductor layer 3 can be prevented at low cost. Furthermore, ion migration of the conductor layer 3 can be prevented by the carbon containing layers 16a, 16b, 17a, 17b, 17c.

Only the carbon containing layer 17a is formed in the portion of the extraction conductor portion 4b above the bend portion B1. In this case, flexibility of the carbon containing layer 17a above the bend portion B1 is well ensured compared to a case where the two carbon containing layers are formed to overlap with each other. Thus, formation of a crack or the like in the carbon containing layer 17a is prevented even though the FPC board 1a is bent along the bend portion B1. Accordingly, the conductor layer 3 is reliably prevented from coming in contact with acid, and the conductor layer 3 is reliably prevented from corroding.

### (6) Still Another Embodiment

A material for the base insulating layer 2 and the solder resist layer 8 is not limited to polyimide. For example, another insulating material such as polyethylene terephthalate, polyethernitrile and polyethersulfone may be used.

A material for the conductor layer 3 is not limited to copper. For example, another metal material such as a copper alloy and aluminum may be used. A resin material used for the carbon containing layers 6, 7a, 7b, 16a, 16b, 17a, 17b, 17c is not limited to polyimide. For example, another resin material such as epoxy resin may be used. Carbon is not limited to carbon black. For example, various carbon materials such as graphite can be used.

### (7) Correspondences between Elements in the Claims and Parts in Embodiments

In the following paragraph, non-limiting examples of correspondences between various elements recited in the claims below and those described above with respect to various preferred embodiments of the present invention are explained.

In the foregoing embodiments, the base insulating layer 2 is an example of an insulating layer, the first regional is an example of a first region, the second region a2 is an example of a second region, the second insulating portion 2b is an example of a third region, the collector portion 3a is an example of a first conductor portion, the collector portion 3b is an example of a second conductor portion, the extraction conductor portion 4a is an example of a first extraction portion, the extraction conductor portion 4b is an example of a second extraction portion, the carbon containing layers 6, 16a, 16b are examples of a first coating layer, the carbon containing layers 7a, 7b, 17a, 17b, 17c and the solder resist layer 8 are examples of a second coating layer, the solder resist layer 8 or the carbon containing layer 17a is an example of a first coating portion, and the carbon containing layers 7a, 7b, 17a, 17b, 17c are examples of a second coating portion. The fuel electrode 35a, the air electrode 35b and the electrolytic film 35c are examples of a cell element.

As each of various elements recited in the claims, various other elements having configurations or functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A printed circuit board used in a fuel cell, comprising:
an insulating layer that has one surface and the other surface while having, on said one surface, first and second regions that are adjacent to each other and a third region that is adjacent to said first region;
a first conductor portion formed on said first region of said insulating layer;
a second conductor portion formed on said second region of said insulating layer;
a first extraction portion that is integrally formed with said first conductor portion and extends from said first region to said third region of said insulating layer;
a second extraction portion that is integrally formed with said second conductor portion and extends from said second region to said third region through said first region of said insulating layer;
a first coating layer formed to cover said first conductor portion and said first extraction portion on at least said first region of said insulating layer; and
a second coating layer formed to cover said second conductor portion and said second extraction portion on at least said first and second regions of said insulating layer, wherein
said insulating layer can be bent at a bend portion between said first region and said second region such that said first region and said second region are opposite to each other,
said second coating layer includes
a first coating portion that covers a portion, above said bend portion of said insulating layer, of said second extraction portion, and
a second coating portion formed on a region of said insulating layer excluding said bend portion,
said first coating layer and said second coating portion of said second coating layer are each made of a resin composition containing carbon, and
said first coating portion of said second coating layer has higher flexibility than the second coating portion of said second coating layer.

2. The printed circuit board according to claim 1, wherein said first coating portion of said second coating layer is made of a resin material.

3. The printed circuit board according to claim 2, wherein a thickness of said first coating portion of said second coating layer is not less than 5 μm and not more than 20 μm, and a thickness of each of said first coating layer and said second coating portion of said second coating layer is not less than 5 μm and not more than 30 μm.

4. The printed circuit board according to claim 1, wherein said first coating portion of said second coating layer is made of a resin composition containing carbon, and a thickness of said first coating portion of said second coating layer is smaller than a thickness of the second coating portion of said second coating layer.

5. The printed circuit board according to claim 4, wherein the thickness of said first coating portion of said second coating layer is not less than 5 μm and not more than 20 μm, and 45 each of a thickness of said first coating layer and the thickness of the second coating portion of said second coating layer is not less than 5 μm and not more than 30 μm.

6. A fuel cell comprising;
the printed circuit board according to claim 1,
a cell element; and
a housing that houses said printed circuit board and said cell element, wherein
said cell element is arranged between said first and second regions in a state where said first and second regions of said insulating layer of said printed circuit board are bent along said bend portion with said one surface as an inner side, and
said third region of said insulating layer is outwardly extracted from said housing such that at least part of said first extraction portion and at least part of said second extraction portion are exposed to an outside of said housing.
